(19) United States
(12) Patent Application Publication
(10) Pub. No.: US 2011/0159864 A1
(43) Pub. Date: Jun. 30, 2011

(54) ELECTRONIC EQUIPMENT MODE SWITCHING APPARATUS AND METHOD BASED ON SKIN CONTACT, MOBILE PHONE FOR SWITCHING CALL INCOMING ALARMING MODE ON THE BASIS OF SKIN CONTACT WHEN CALL IS RECEIVED, AND METHOD OF AUTOMATICALLY SWITCHING CALL INCOMING ALARMING MODE OF THE MOBILE PHONE

(76) Inventors: June Min Park, Seoul (KR); David Chong, Carlsbad, CA (US)

(21) Appl. No.: 12/898,173

(22) Filed: Oct. 5, 2010

(30) Foreign Application Priority Data
Dec. 29, 2009 (KR) 10-2009-0132576
May 18, 2010 (KR) 10-2010-0046253

(51) Int. Cl. H04M 3/00; H03K 17/60

(52) U.S. Cl. 455/418; 327/482

(57) ABSTRACT

The present invention relates to an electronic equipment mode switching apparatus and method based on a skin contact made by a user using the electronic equipment, thereby being capable of minimizing the power consumption of electronic equipment and also of instantly operating electronic equipment as soon as skin contact is made. The electronic equipment mode switching apparatus includes skin contact detection means for detecting electricity generated when a user's skin is touched, logic circuit means for generating a mode switching signal to switch a power supply mode of an electronic device when skin contact is detected by the skin contact detection means, and mode switching means for switching the power supply mode of the electronic device in response to the mode switching signal generated by the logic circuit means.

### FIELD OF THE INVENTION

The present invention relates to automatically switching the mode of an electronic device. More particularly, the present invention relates to an electronic equipment mode switching apparatus and method based on a skin contact made by a user who uses the electronic equipment, a mobile phone capable of switching a call incoming alarming mode on the basis of a skin contact when a call is received, and a method of automatically switching the call incoming alarming mode of the mobile phone, thereby being capable of minimizing the power consumption of electronic equipment and also of instantly operating electronic equipment as soon as skin contact is made.

### BACKGROUND OF THE INVENTION

In general, a great number of electronic devices are being used at home or by people. For example, electronic devices, such as TV, a refrigerator, a computer, a washing machine, a microwave oven, an electric iron, a hair dryer, a bidet, an air conditioner, and an electric fan, are being used at home. Furthermore, people use a mobile phone, a digital camera, an MP3 player, a portable media player (PMP), a wrist watch, and iPad. The electronic device is directly connected to a power source and operated or supplied with electricity from a battery for supplying a power source and operated. Furthermore, the electronic device includes a switch for supplying the power source thereto when the switch is turned on or off. When the power source is supplied, the electronic device is operated. In general, during the time for which the device is not used, the power source of the switch is set to the off state.

Meanwhile, research is being done on power-saving products in order to reduce power consumption. Furthermore, users are using products in various ways, such as turning off a power source when a product is not used or using the socket having a switch attached thereto.

However, there are many electronic devices which have not yet been developed into power-saving products. If a user does not use the socket although a switch is attached to the socket, electric power is indiscreetly consumed. For example, in the case of an electric iron, during the time for which a user is doing other things, such as answering the phone, while using the electric iron, a power source continues to be supplied to the electric iron and thus electric power is consumed. For another example, in the case in which a user has to suddenly take an important scene using a digital camera, the user has to set the power mode switch of the digital camera to a power-on state. In such a case, the user misses the important scene and does not take the important scene.

In other words, a conventional electronic device is problematic in that electric power is unnecessarily consumed when the device is not used and unnecessary operations, such as an operation of turning on the power mode switch in order to use the device, are required.

### SUMMARY OF THE INVENTION

Accordingly, the present invention has been made in view of the above problems occurring in the prior art, and it is an object of the present invention to provide an electronic equipment mode switching apparatus and method based on a skin contact made by a user who uses the electronic equipment, thereby being capable of minimizing the power consumption of electronic equipment and also of instantly operating electronic equipment as soon as skin contact is made.

To achieve the above object, according to an aspect of the present invention, there is provided an electronic equipment mode switching apparatus based on a skin contact, including skin contact detection means for detecting electricity generated when a user's skin is touched; logic circuit means for generating a mode switching signal to switch a power supply mode of an electronic device when skin contact is detected by the skin contact detection means; and mode switching means for switching the power supply mode of the electronic device in response to the mode switching signal generated by the logic circuit means.

To achieve the above object, according to another aspect of the present invention, there is provided a mode switching method of the electronic equipment mode switching apparatus, including the steps of when a skin is touched in a first mode in which an electronic device driven by electricity is operating or idle, generating a signal for switching a mode of the electronic device to electronic equipment mode switching means for switching a power supply mode of the electronic device; the mode of the electronic device entering a second mode; making a determination of whether the skin remains touched and, if, as a result of the determination, the skin does not remain touched, generating a signal for switching a mode of the electronic device to the electronic equipment mode switching means of the electronic device; and the electronic device returning to the first mode.

To achieve the above object, according to yet another aspect of the present invention, there is provided a mobile phone capable of switching a call incoming alarming mode based on a skin contact when a call is received, including a communication module for providing communication between the mobile phone and a mobile communication network; a memory unit for storing at least one of a sound output mode, a vibration generation mode, an illumination generation mode, a silence mode, and a screen output mode, which is set as the call incoming alarming mode of the mobile phone for the call received through the communication module over the mobile communication network; a touch detection unit for detecting a skin contact when the call is received over the mobile communication network; and a control unit for performing control so that the sound output mode is switched to at least one of the vibration generation mode, the illumination generation mode, the silence mode, and the screen output mode when the skin contact is detected by the touch detection unit in a state in which the call incoming alarming mode is the sound output mode, based on the call incoming alarming mode set in the memory unit when the call is received and a result of the detection of the touch detection unit.

To achieve the above object, according to further yet another aspect of the present invention, there is provided a method of switching a call incoming alarming mode of a mobile phone, including the steps of when a call is received by the mobile phone, setting the call incoming alarming mode; when a call is received by the mobile phone, searching for the call incoming alarming mode and, if, as a result of the search, the call incoming alarming mode is a sound output mode, making a determination of whether the mobile phone is touching a user's skin; if, as a result of the determination, the mobile phone is not touching the user's skin, outputting sound; making a determination of whether the user's skin is touching the mobile phone during the sound output; and if, as a result of the determination, the user's skin is touching the mobile phone during the sound output, stopping the sound output and switching the call incoming alarming mode to a mode other than the sound output.

### BRIEF DESCRIPTION OF THE DRAWINGS

Further objects and advantages of the invention can be more fully understood from the following detailed description taken in conjunction with the accompanying drawings in which:

FIG. 1 is a block diagram of an electronic equipment mode switching apparatus based on a skin contact according to the present invention;

FIG. 2 is a circuit diagram of the electronic equipment mode switching apparatus shown in FIG. 1 according to an embodiment of the present invention;

FIG. 3 is a block diagram showing a first embodiment in which the electronic equipment mode switching apparatus based on a skin contact according to the present invention is applied;

FIG. 4 is a block diagram showing a second embodiment in which the electronic equipment mode switching apparatus based on a skin contact according to the present invention is applied;

FIG. 5 is a block diagram showing a third embodiment in which the electronic equipment mode switching apparatus based on a skin contact according to the present invention is applied;

FIG. 6 is a block diagram showing a fourth embodiment in which the electronic equipment mode switching apparatus based on a skin contact according to the present invention is applied;

FIG. 7 is a block diagram showing a fifth embodiment in which the electronic equipment mode switching apparatus based on a skin contact according to the present invention is applied;

FIG. 8 is a block diagram showing a sixth embodiment in which the electronic equipment mode switching apparatus based on a skin contact according to the present invention is applied;

FIG. 9 is a flowchart illustrating a method of switching the mode of an electronic device on the basis of a skin contact according to an embodiment of the present invention;

FIG. 10 is a block diagram of a mobile phone capable of switching a call incoming alarming mode on the basis of a skin contact when a call is received according to an embodiment of the present invention;

FIG. 11 is a diagram showing a state in which a conductive material is formed in a mobile phone according to a first embodiment of the present invention;

FIG. 12 is a diagram showing a state in which a conductive material is formed in a mobile phone according to a second embodiment of the present invention; and

FIG. 13 is a flowchart illustrating a method of automatically switching the call incoming alarming mode of a mobile phone on the basis of a skin contact when a call is received according to an embodiment of the present invention.

### DESCRIPTION OF REFERENCE NUMERALS OF PRINCIPAL ELEMENTS IN THE DRAWINGS

100: electronic equipment mode switching apparatus

110: skin contact detection means 111: timer

120: logic circuit means 121: first logic circuit unit

122: second logic circuit unit 130: mode switching means

200: electronic device 220: power supply means

210: electronic equipment mode switching means

230: shutter driving means 240: heating plate means

250: toilet seat heating means 260: display means

270: heating and ventilation means 280: motor means

310: communication module 320: memory unit

330: touch detection unit 340: sound output unit

350: vibration generation unit 370: screen output unit

360: illumination generation unit 380: control unit

390: timer unit 400: mobile phone

410: thin metal plate 420: mobile phone casing

430: thin metal film

### DETAILED DESCRIPTION OF THE PREFERRED EMBODIMENTS

Some embodiments of the present invention will now be described in detail with reference to the accompanying drawings.

Furthermore, in describing the embodiments, a description of techniques which are well known in the art to which the present invention pertains and not directly relevant to the present invention is omitted in order to make the gist of the present invention unnecessarily vague.

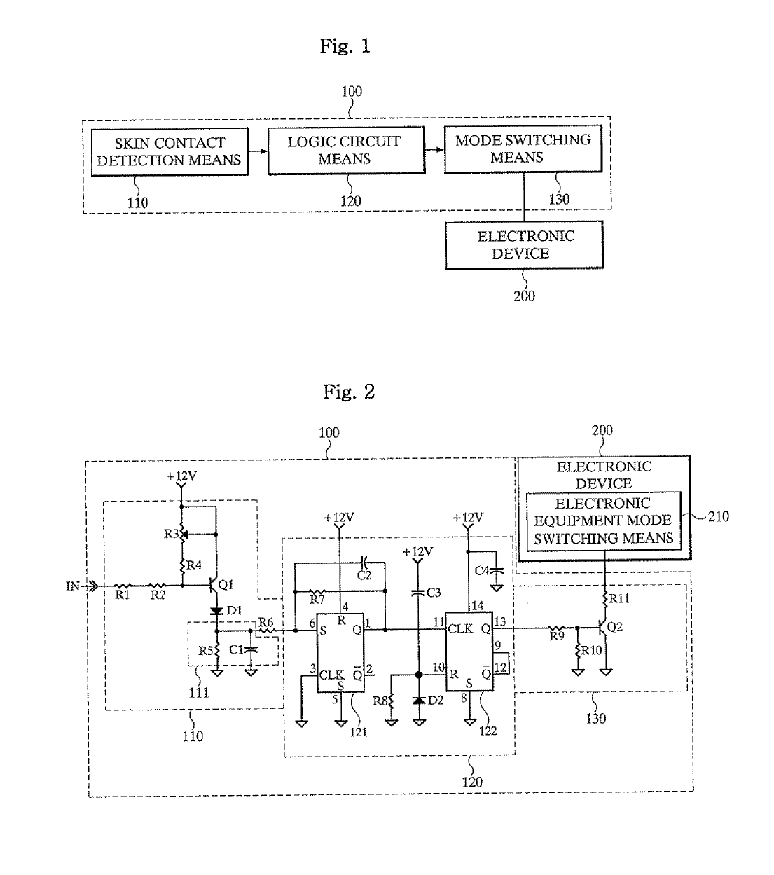

FIG. 1 is a block diagram of an electronic equipment mode switching apparatus 100 based on a skin contact according to the present invention. The electronic equipment mode switching apparatus 100 according to the present invention, as shown in FIG. 1, includes skin contact detection means 110, logic circuit means 120, and mode switching means 130. The skin contact detection means 110 detects electricity generated when a user's skin is touched and sends the detected electricity to the logic circuit means 120. When skin contact is detected by the skin contact detection means 110, the logic circuit means 120 generates a signal for switching the power supply mode of an electronic device 200. The mode switching means 130 switches the power supply mode of the electronic device 200. For example, if the power supply mode of the electronic device 200 is in the power-on state, the mode switching means 130 switches the power supply mode to the power-off state. If the power supply mode of the electronic device 200 is in the power-off state, the mode switching means 130 switches the power supply mode to the power-on state.

FIG. 2 is a circuit diagram of the electronic equipment mode switching apparatus 100 shown in FIG. 1 according to an embodiment of the present invention. The electronic equipment mode switching apparatus 100 includes skin contact detection means 110 consisting of a skin contact detection circuit, logic circuit means 120 consisting of logic circuits, and mode switching means 130 consisting of a mode switch circuit. Here, the skin contact detection means 110 includes a first switching unit Q1 configured to perform an on or off switching operation in response to skin contact and a timer 111. The base terminal of the first switching unit Q1 is connected to the output terminal of first and second resistors R1 and R2 which are in series connected to a skin contact input terminal IN. Furthermore, the emitter terminal of the first switching unit Q1 is connected to an internal power source 12V. Furthermore, the collector terminal of the first switching unit Q1 is connected to the anode of a first diode D1. Meanwhile, third and fourth resistors R3 and R4 are in series connected to the internal power source 12V. The output terminal of the fourth resistor R4 is connected between the second resistor R2 and the base terminal of the first switching unit Q1. Furthermore, the cathode of the first diode D1 is connected to one terminal of a fifth resistor R5, one terminal of a first capacitor C1, and one terminal of a sixth resistor R6. The other terminal of the fifth resistor R5 and the other terminal of the first capacitor C1 are connected to the ground. Furthermore, the fifth resistor R5 and the first capacitor C1 are constructed in parallel, thus forming the timer 111. Furthermore, the other terminal of the sixth resistor R6 is connected to the input terminal of the logic circuit means 120. Through the above circuit configuration, when a user's skin touches the electronic equipment mode switching apparatus 100, electricity generated from the user is discharged to the skin contact input terminal TN and thus the first switching unit Q1 is turned on. In other words, when a user's skin touches the electronic equipment mode switching apparatus 100, the capacitance of the user generates a minute base input voltage which can turn on the first switching unit Q1.

The logic circuit means 120 can include a first logic circuit unit 121 and a second logic circuit unit 122. Here, the internal power source 12V is connected to the R pin of the first logic circuit unit 121, and the output of the skin contact detection means 110 is inputted to the S pin of the first logic circuit unit 121. Furthermore, the Q pin of the first logic circuit unit 121 is connected to the CLK terminal of a second logic circuit unit 122. Meanwhile, the CLK and D pins of the first logic circuit unit 121 are connected to the ground, and the Q̅ pin of the first logic circuit unit 121 is opened. Furthermore, a seventh resistor R7 and a second capacitor C2 are constructed in parallel between the S pin and the Q pin of the first logic circuit unit 121. That is, the seventh resistor R7 and the second capacitor C2 construct a time constant circuit. Furthermore, the CLK pin of the second logic circuit unit 122 is connected to the Q pin of the first logic circuit unit 121, and the Q pin of the second logic circuit unit 122 is connected to the mode switching means 130. Meanwhile, the D and Q̅ pins of the second logic circuit unit 122 are short-circuited, and the R pin thereof is connected to the ground. Furthermore, the R pin of the second logic circuit unit 122 is connected to one terminal of a third capacitor C3, the cathode of a second diode D2, and one terminal of an eighth resistor R8. Here, the other terminal of the eighth resistor R8 and the anode of the second diode D2 are connected to the ground. The eighth resistor R8 and the second diode D2 are connected to each other in parallel. Meanwhile, the other terminal of the third capacitor C3 is connected to the internal power source 12V. Here, the first logic circuit unit 121 can consist of a Schmidt trigger circuit for obtaining a stable characteristic having a high noise margin, and the second logic circuit unit 122 can consist of a flip-flop circuit capable of performing a sequential output according to an output value of the first logic circuit unit 121.

The mode switching means 130 includes a second switching unit Q2 having a base terminal for receiving the output of the logic circuit means 120. A ninth resistor R9 is connected in series between the output terminal of the logic circuit means 120 and the base terminal of the second switching unit Q2. A tenth resistor R10 is connected between the ground and one terminal of the ninth resistor R9. Meanwhile, one terminal of an eleventh resistor R11 is connected to the collector terminal of the second switching unit Q2, and the electronic device 200 is connected to the other terminal of the eleventh resistor R11. The emitter terminal of the second switching unit Q2 is connected to the ground. Accordingly, when the second switching unit Q2 is turned on or off, the mode of electronic equipment mode switching means 210 can be switched.

An operation of the electronic equipment mode switching apparatus based on a skin contact according to an embodiment of the present invention is described below. First, when a user's skin (e.g., the back of the hand, the palm of the hand, or a finger) touches the skin contact detection means 110, the first switching unit Q1 of the skin contact detection means 110 is turned on (i.e., ON state) in response to electricity generated from the user's skin. When the first switching unit Q1 is turned on, the timer 111 consisting of the fifth resistor R5 and the first capacitor C1 starts to be charged. When the charging of the timer 111 is completed after a lapse of some time according to a set time constant value, a logic high signal ‘1’ is inputted to the S pin (Pin No. 6) of the first logic circuit unit 121 of the logic circuit means 120.

Meanwhile, when the logic high signal ‘1’ is inputted to the S pin of the first logic circuit unit 121, a logic high signal ‘1’ is output from the Q pin (Pin No. 1) of the first logic circuit unit 121 of the logic circuit means 120. The logic high signal of the first logic circuit unit 121 is inputted to the CLK pin (Pin No. 11) of the second logic circuit unit 122. Furthermore, a logic high signal ‘1’ is outputted from the Q pin (Pin No. 13) of the second logic circuit unit 122 and then inputted to the mode switching means 130.

When the logic high signal is outputted from the logic circuit means 120, the second switching unit Q2 of the mode switching means 130 is turned on (i.e., ON state). In response to the logic high signal, the mode of the electronic device 200 connected to the eleventh resistor R11 is switched.

Thereafter, when the user's skin (e.g., the hand) does not touch the skin contact detection means 110, the first switching unit Q1 of the skin contact detection means 110 is turned off (i.e., OFF state). When the first switching unit Q1 is turned off, the timer 111 consisting of the fifth resistor R5 and the first capacitor C1 starts to be discharged. When the discharging of the timer 111 is completed according to a set time constant value, a logic low signal ‘0’ is inputted to the S pin (Pin No. 6) of the first logic circuit unit 121 of the logic circuit means 120.

Meanwhile, when the logic low signal ‘0’ is inputted to the S pin (Pin No. 6) of the first logic circuit unit 121, a logic low signal ‘0’ is output from the Q pin (Pin No. 1) of the first logic circuit unit 121. The logic low signal of the first logic circuit unit 121 is inputted to the CLK pin (Pin No. 11) of the second logic circuit unit 122. Furthermore, a logic low signal ‘0’ is output from the Q pin (Pin No. 13) of the second logic circuit unit 122 and then inputted to the mode switching means 130.

When the logic low signal ‘0’ is output from the logic circuit means 120, the second switching unit Q2 of the mode switching means 130 is turned off (i.e., OFF state). In response thereto, the mode of the electronic equipment mode switching means 210 of the electronic device 200, which is connected to the eleventh resistor R11, is switched again. In the mode switching of the electronic device 200, the power supply mode of the electronic device 200 can be switched to the on or off mode or an operating state of the electronic device 200 is changed according to the type of an electronic device. The mode switching of the operating state can include bell/vibration generation mode switching in the case of a mobile phone.

Here, the time that the mode of the electronic equipment mode switching means 210 within the electronic device 200 takes to be switched can be controlled by controlling the resistance of the fifth resistor R5 and the capacitance of the first capacitor C1, which constitute the timer 111 of the skin contact detection means 110. Such time control can be set in various ways according to the type or specification of an electronic device. For example, a low power electronic device can include the timer 111 for switching the power supply mode relatively fast because it requires a relatively small load for switching power as compared with a high power electronic device.

Meanwhile, the circuit diagram of the electronic equipment mode switching apparatus based on a skin contact according to the embodiment of the present invention is for convenience of description. It is preferred that the electronic equipment mode switching apparatus be configured in the control module of a corresponding electronic device in the form of a semiconductor circuit.

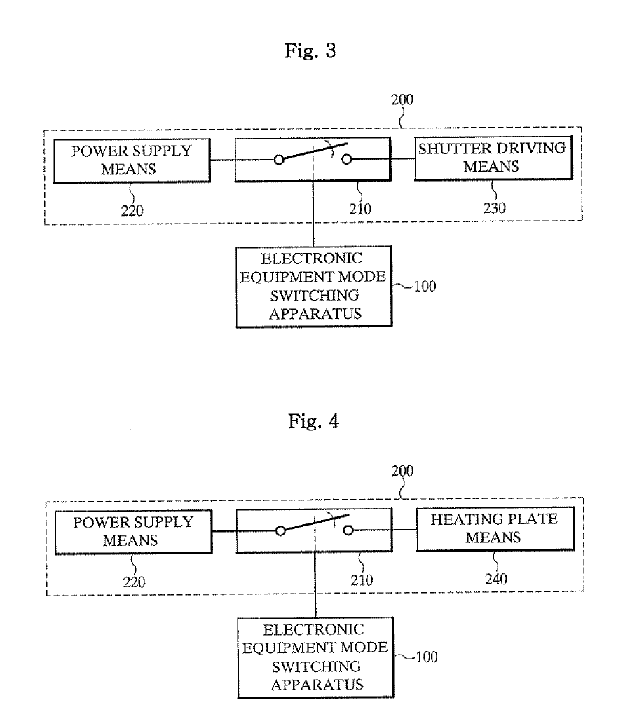

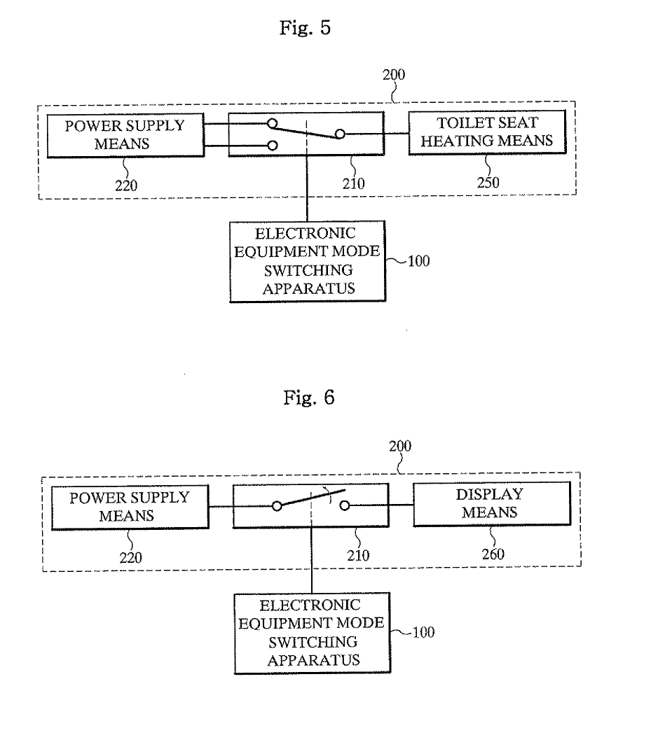

FIG. 3 is a block diagram showing a first embodiment in which the electronic equipment mode switching apparatus based on a skin contact according to the present invention is applied. The first embodiment in which the electronic equipment mode switching apparatus according to the present invention is used can correspond to a case in which the electronic equipment mode switching apparatus is applied to, for example, a digital camera. In the case in which the electronic equipment mode switching apparatus 100 is applied to a digital camera, a corresponding electronic device 200 includes the electronic equipment mode switching means 210, power supply means 220, and shutter driving means 230. Here, the power supply means 220 can be a battery, and the electronic equipment mode switching means 210 is a power switch for switching on or off a power source supplied from the power supply means 220 to the shutter driving means 230 for driving the camera shutter of the digital camera.

In general, the power switch of a digital camera must be turned on so that a picture can be taken. Here, the digital camera is chiefly carried and thus a battery is used as a power source. Accordingly, at normal times, a user turns off the power source of the digital camera in order to prevent the consumption of the battery power. Next, when a picture is sought to be taken, the user turns on the power source by manipulating the power switch, drives the shutter, and takes a picture. In this case, there are problems in that a user has to turn on the power source by manipulating the power switch whenever a picture is taken and may miss an opportunity to drive the shutter at the moment when the power switch is turned on.

The above problems can be solved by automatically switching on the electronic equipment mode switching means 210 using the electronic equipment mode switching apparatus 100. More particularly, in general, the shutter of a digital camera is placed on the upper right side of the digital camera. Furthermore, a strap is configured on the right side of the digital camera and wound on the wrist of the right hand or the palm of the right hand in order to prevent the digital camera from falling to the ground although the main body of the digital camera is taken off from the hand. The user of the digital camera drives the shutter while seeing a viewfinder or a liquid crystal monitor in the state in which the user holds the camera using both hands. If the electronic equipment mode switching apparatus 100 shown in FIGS. 1 and 2 is configured on the surface of a part which is grasped by the left hand in order for the user to take a picture, from the main body of the digital camera, the digital camera can be automatically turned on when the skin of the user's left hand touches the electronic equipment mode switching apparatus 100. Here, the part touched by the skin of the user's left hand can be selected in various ways depending on experiments or field experiences according to a digital camera. Furthermore, when the user's left hand is taken off from the digital camera, the mode of the electronic equipment mode switching means 210 is automatically switched off by the electronic equipment mode switching apparatus 100. In other words, the digital camera is automatically turned on when the user's left hand touches the digital camera and is automatically switched off when the user's left hand is taken off from the digital camera. Accordingly, a user can use a digital camera more conveniently and also take more opportunities to take pictures, which would have been missed because of an additional operation of turning on the power switch of a digital camera.

FIG. 4 is a block diagram showing a second embodiment in which the electronic equipment mode switching apparatus based on a skin contact according to the present invention is applied. The second embodiment in which the electronic equipment mode switching apparatus 100 according to the present invention is used can correspond to a case in which the electronic equipment mode switching apparatus 100 is applied to, for example, an electric iron. In the case in which the electronic equipment mode switching apparatus 100 is applied to an electric iron, a corresponding electronic device 200 includes the electronic equipment mode switching means 210, the power supply means 220, and heating plate means 240. Here, the power supply means 220 can be an AC power source or a battery, and the electronic equipment mode switching means 210 is a power switch for switching on or off a power source supplied from the power supply means 220 to the heating plate means 240 of the electric iron.

After using an electric iron, a housewife some times does not clearly remember whether she has turned off the power source of the electric iron. There will be no serious problem if she pulled the plug of the electric iron out of the socket. However, if it is not clear whether the plug of the electric iron has been pulled out of the socket, there will be a serious problem. This problem results in not only unnecessary power consumption, but also a fire because the electric iron consumes a lot of electric power. For another example, during the time for which a user is doing other things after making an electric iron stand because of an incoming call or other urgent tasks during the use of the electric iron, electric power continues to be consumed. Furthermore, there is a problem in that during the time for which a user is doing other tasks after making an electric iron stand, if a child or an adult carelessly has part (e.g., the hands or a foot) of its or his body touched the heating plate of the electric iron or brings down the electric iron down, the touched part of the body can be burned or a fire can be generated.

The above problems can be solved by automatically switching on or off the electronic equipment mode switching means 210 using the electronic equipment mode switching apparatus 100. More particularly, in general, an electric iron is supplied with electric power on the basis of a temperature set by a user. If the electronic equipment mode switching apparatus 100 shown in FIGS. 1 and 2 is configured on the surface of a handle part which is grasped by a user, from the main body of the electric iron, a power source can be supplied to the heating plate means 240 of the electric iron when the user's skin touches the electronic equipment mode switching apparatus 100. Here, the part that the user's skin is touched can include one or more of the top surface, the bottom surface, and both the top and bottom surfaces of the handle according to experiments or field experiences depending on an electric iron. Furthermore, when the user's hand is taken off from the handle of the electric iron, the electronic equipment mode switching means 210 is automatically switched off through the electronic equipment mode switching apparatus 100. In other words, the electronic equipment mode switching apparatus 100 is automatically turned on when the user holds the handle of the electric iron by the hand and is automatically switched off when the user's hand is taken off from the handle of the electric iron in order to do other things or an urgent task. Accordingly, the user can use the electric iron more conveniently and safely.

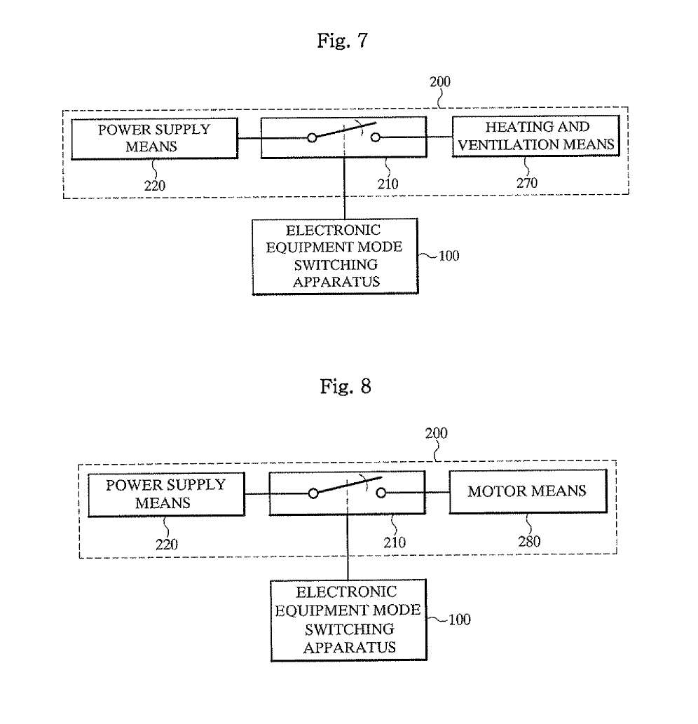

FIG. 5 is a block diagram showing a third embodiment in which the electronic equipment mode switching apparatus based on a skin contact according to the present invention is applied. The third embodiment in which the electronic equipment mode switching apparatus according to the present invention is used can correspond to a case in which the electronic equipment mode switching apparatus is applied to, for example, a toilet seat. In the case in which the electronic equipment mode switching apparatus 100 is applied to a toilet seat, a corresponding electronic device 200 includes the electronic equipment mode switching means 210, the power supply means 220, and toilet seat heating means 250. Here, the power supply means 220 can be an AC power source. Furthermore, the electronic equipment mode switching means 210 is a power switch for switching a power source, supplied from the power supply means 220 to the toilet seat heating means 250, so that one of first electric power (i.e., low electric power) and second electric power (i.e., electric power relatively higher than the first electric power) is supplied to the toilet seat heating means 250.

For example, one of first electric power (i.e., having the lowest temperature) and second electric power (i.e., having an optimal temperature relatively higher than the temperature of the first electric power) can be supplied through the electronic equipment mode switching apparatus 100 by switching the electronic equipment mode switching means 210. Here, the lowest temperature can be defined to be a temperature at which a user's skin does not feel cold, and the optimal temperature can be defined to be a temperature at which a user's skin feels warm. The lowest and optimal temperatures can be set on the basis of field experiences, experiments, or the existing data. Furthermore, it is preferred that the lowest and optimal temperatures be differently set according to seasons. In other words, a lower temperature can be set in the summer season as compared with the winter season, and a higher temperature can be set in the winter season as compared with the summer season.

If the electronic equipment mode switching apparatus 100 shown in FIGS. 1 and 2 is configured on the surface of a part which is touched by a user's skin, from the toilet seat, the first electric power (i.e., having the lowest temperature) is supplied to the toilet seat heating means 250 at normal times. In this state, when the user's skin touches the electronic equipment mode switching apparatus 100, the electronic equipment mode switching apparatus 100 switches the electronic equipment mode switching means 210 so that the second electric power (i.e., having an optimal temperature) is supplied to the toilet seat heating means 250 of the toilet seat. Here, the part touched by the user's skin can be selected in various ways according to the types of toilet seats, users (e.g., men and women, children, the old and the weak, and handicapped users), experiments, or field experiences.

FIG. 6 is a block diagram showing a fourth embodiment in which the electronic equipment mode switching apparatus based on a skin contact according to the present invention is applied. The fourth embodiment in which the electronic equipment mode switching apparatus 100 according to the present invention is used can correspond to a case in which the electronic equipment mode switching apparatus is applied to, for example, a portable display device, such as a digital wrist watch, iPad, or a portable multimedia player (PMP). In the case in which the electronic equipment mode switching apparatus 100 is applied to the digital wrist watch or the portable multimedia player (PMP), a corresponding electronic device 200 includes the electronic equipment mode switching means 210, the power supply means 220, and display means 260. Here, the power supply means 220 can be a battery, and the electronic equipment mode switching means 210 is a power switch for switching on or off a power source supplied from the power supply means 220 to the display means 260 of the digital wrist watch or the portable multimedia player (PMP).

In general, a user wears the digital wrist watch on his wrist and watches the time displayed on the display means 260 of the wrist watch. Furthermore, a user sees the display means 260 of a portable display device while holding it by the user. Here, when the user goes to bed or has a shower, the digital wrist watch is untied from the wrist. Here, what the digital wrist watch is untied from the user's wrist is detected, and electric power is not supplied to the display means 260 unless a user's skin is detected. Furthermore, in the case in which a user holds the outer frame of the display means 260 of a portable display device, such as iPad or a portable multimedia player, a power source is supplied from the power supply means 220 to the display means 260. However, in the case in which a user does not hold the outer frame of the portable display device, a power source is supplied from the power supply means 220 to the display means 260. Of course, the portable display device can further include a switch which enables a user to use the portable display device on the desk or his knee. Here, in the case of the digital wrist watch, a part touched by the user's skin is the back side of the digital wrist watch and thus the electronic equipment mode switching apparatus 100 is configured on the back side of the digital wrist watch. Furthermore, in the case of a portable display device, such as iPad or a portable multimedia player, the electronic equipment mode switching apparatus 100 can be formed at a point which is easy to grasp using the hand, from the outer frame of the portable display device, according to experiments or field experiences.

FIG. 7 is a block diagram showing a fifth embodiment in which the electronic equipment mode switching apparatus based on a skin contact according to the present invention is applied. The fifth embodiment in which the electronic equipment mode switching apparatus 100 according to the present invention is used can correspond to a case in which the electronic equipment mode switching apparatus is applied to, for example, a hair dryer. In the case in which the electronic equipment mode switching apparatus 100 according to the present invention is applied to the hair dryer, a corresponding electronic device 200 includes the electronic equipment mode switching means 210, the power supply means 220, and heating and ventilation means 270. Here, the power supply means 220 can be an AC power source or a battery, and the electronic equipment mode switching means 210 is a power switch for switching on or off a power source supplied from the power supply means 220 to the heating and ventilation means 270 of the hair dryer.

In general, the hair dryer is one of high power electronic devices and used to dry hair after a shampoo and to set various styles for hair. The hair dryer has also to be turned on using an additional power switch. If a user is sought to temporarily pull down the hair dryer while using the hair dryer, the user has to turn off the power switch of the hair dryer. If the user keeps the hair dryer turned on because he feels inconvenient to repeatedly turn on or off the power switch, unnecessary electric power is consumed. In particular, with the recent appearance of a wireless hair dryer using a battery as its power source, user convenience has been improved. In such a wireless hair dryer, it is necessary to minimize unnecessary power consumption.

The above inconvenience or problems can be solved by automatically switching on or off the electronic equipment mode switching means 210, embedded in the main body of the hair dryer, using the electronic equipment mode switching apparatus 100. More particularly, switches for modes, such as power-off, ventilation, low output, and high output, are basically formed in the handle part of the hair dryer. Furthermore, a user has his hair remodeled using one of the ventilation, low output, and high output modes by manipulating a corresponding switch. Here, the user can search for a brush while remodeling his hair in one of the ventilation, low output, and high output modes or can take off his hand from the hair dryer in order to answer the phone. If the electronic equipment mode switching apparatus 100 shown in FIGS. 1 and 2 is configured in the handle part of the main body of the hair dryer, the hair dryer can be automatically switched off when the user's skin is taken off from the handle. Furthermore, when the user grasps the handle of the hair dryer by the hand, the electronic equipment mode switching means 210 can be automatically turned on through the electronic equipment mode switching apparatus 100. Accordingly, the user can use the hair dryer more conveniently, and unnecessary power consumption can be reduced.

FIG. 8 is a block diagram showing a sixth embodiment in which the electronic equipment mode switching apparatus based on a skin contact according to the present invention is applied. The sixth embodiment in which the electronic equipment mode switching apparatus 100 according to the present invention is used can correspond to a case in which the electronic equipment mode switching apparatus is applied to, for example, a vacuum cleaner or an electric fan. In the case in which the electronic equipment mode switching apparatus 100 according to the present invention is applied to the vacuum cleaner or the electric fan, a corresponding electronic device 200 includes the electronic equipment mode switching means 210, the power supply means 220, and motor means 280. Here, the power supply means 220 can be an AC power source or a battery, and the electronic equipment mode switching means 210 is a power switch for switching on or off a power source supplied from the power supply means 220 to the motor means 280 of the vacuum cleaner or the electric fan.

In general, the vacuum cleaner or the electric fan is driven by a motor. The vacuum cleaner or the electric fan has also to be turned on using an additional power switch. If a user is sought to temporarily pull down the vacuum cleaner while using the vacuum cleaner, the user has to turn off the power switch of the vacuum cleaner. If the user keeps the vacuum cleaner turned on because he feels inconvenient to repeatedly turn on or off the power switch, unnecessary electric power is consumed. In particular, in a small-sized wireless vacuum cleaner, a battery is used as the power source of the wireless vacuum cleaner. In such a wireless vacuum cleaner, the battery can be discharged during the use of the wireless vacuum cleaner. It is therefore necessary to more efficiently use the electric power of the wireless vacuum cleaner than a wired vacuum cleaner having a plug directly connected to the socket.

The above inconvenience or problems can be solved by automatically switching on or off the electronic equipment mode switching means 210, embedded in the main body of the vacuum cleaner, using the electronic equipment mode switching apparatus 100. More particularly, switches for operating the vacuum cleaner from a power-off mode to a low output mode or a high output mode in a sliding manner is installed in the handle part of the vacuum cleaner. For example, a user can clean up a house by manipulating a corresponding switch. During cleaning, the user can have the vacuum cleaner taken off from his hand in order to open the front door or answer the phone. If the electronic equipment mode switching apparatus 100 shown in FIGS. 1 and 2 is configured in the handle part of the main body of the vacuum cleaner, the vacuum cleaner can be automatically switched off when the user's skin is taken off from the handle of the vacuum cleaner. Furthermore, when the user grasps the handle of the vacuum cleaner, the electronic equipment mode switching means 210 can be automatically turned on through the electronic equipment mode switching apparatus 100. Accordingly, the user can use the vacuum cleaner more conveniently, and unnecessary power consumption can be reduced.

Meanwhile, an electric fan includes a stand having switches installed therein, wings, a motor, a protection net, and a pivot axle. The motor of the electric fan is driven by manipulating the switch and thus the fan is rotated. Here, the electric fan consumes relatively low power, but is operated for a long time in a hot weather, and a user can be injured by the fan of the electric fan. In other words, the fingers of a child or an adult can be injured by the fan of the electric fan, rotated by the motor. In particular, the fingers of an infant or a careless child can be deadly injured by the rotating fan of the electric fan.

The above inconvenience or problems can be solved by automatically switching on or off the electronic equipment mode switching means 210, embedded in the main body of the electric fan, using the electronic equipment mode switching apparatus 100. More particularly, once the electric fan is turned on, the electric fan continues to be operated until it is automatically turned off by a timer. Here, an infant, a child, or a careless adult come close to the electric fan, and their fingers can be inserted into the gaps of the protection net of the electric fan, resulting in injuries. In order to avoid the problem, the electronic equipment mode switching apparatus 100 shown in FIGS. 1 and 2 can be configured in the protection net of the electric fan or the front side of the main body of the electric fan other than the switches of the main body of the electric fan. When a user's skin touches the main body or the protection net of the electric fan, the electric fan can be automatically turned off. In particular, if the electric fan is set to automatically turn off when the skin or the hands of an infant or a child approaches and touches the main body of the electric fan, the infant or the child can be safely protected from the wings of the electric fan. Furthermore, when a user's skin is taken off from the main body or the protection net of the electric fan, the electronic equipment mode switching means 210 is automatically turned on through the electronic equipment mode switching apparatus 100. Accordingly, a user can use the electric fan more safely.

Meanwhile, in the electronic equipment mode switching apparatus based on a skin contact according to the present invention, it is advantageous for the skin contact detection means 110 of the electronic equipment mode switching apparatus 100 to more easily detect electricity generated by a user. To this end, it is preferred that a material having excellent conductivity (e.g., aluminum (Al)) be deposited on a surface casing of the electronic device 200. For example, in the case in which the electronic device 200 is a digital camera, the material having excellent conductivity is formed at a place touched by the left hand of a user who uses the digital camera. For another example, in the case in which the electronic device 200 is an electric iron, a hair dryer, or a vacuum cleaner, the material having excellent conductivity is formed at the handle part. For yet another example, in the case in which the electronic device 200 is a toilet seat, the material having excellent conductivity is formed on the top surface of the toilet seat. For yet another example, in the case in which the electronic device 200 is a digital wrist watch, the material having excellent conductivity is formed at a part touched by the back of the hand of a user. For yet another example, in the case in which the electronic device 200 is a portable display device, a frame formed in the contour of the portable display device is made of the material having excellent conductivity is formed.

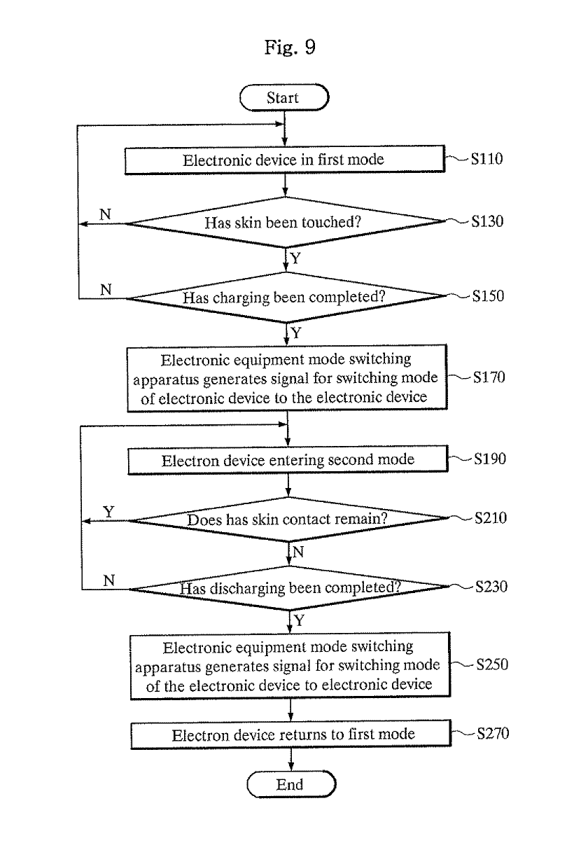

FIG. 9 is a flowchart illustrating a method of switching the mode of an electronic device on the basis of a skin contact according to an embodiment of the present invention. In the method of switching the mode of an electronic device on the basis of a skin contact according to the embodiment of the present invention, as shown in FIG. 9, the electronic device operated by electricity is in a first mode in which the electronic device is idle or operating at step S110. Here, the electronic device 200 can include, for example, a digital camera, an electric iron, a toilet seat, a digital wrist watch, a portable display device, a hair dryer, a vacuum cleaner, and an electric fan. Furthermore, the electronic device 200 in the first mode (i.e., an idle state) starts to be operated when a user's skin is touched and can include a digital camera, an electric iron, a digital wrist watch, a portable display device, a hair dryer, and a vacuum cleaner. Furthermore, the electronic device 200 in the first mode (i.e., an operating state) has its operation stopped when a user's skin is touched and can include an electric fan. Meanwhile, as an exceptional electronic device, a toilet seat is in the idle mode when the first mode is the lowest temperature.

The electronic equipment mode switching apparatus 200 determines whether a user's skin is touched thereon at step S130. Here, if electricity is generated from the user's skin, it is determined that the user's skin has touched the electronic equipment mode switching apparatus 100. If, as a result of the determination at step S130, the user's skin touches the electronic equipment mode switching apparatus 100, charging is started through the timer 111. It is then determined whether the charging has been completed at step S150. If, as a result of the determination at step S150, the charging has been completed, it means that the user has started to use the electronic device 200 or the user is in a state in which the user is in danger because of the electronic device 200. In this case, the electronic equipment mode switching apparatus 100 generates a signal for switching the mode of the electronic device 200 to the electronic equipment mode switching means 210 of the electronic device 200 at step S170.

In response to the signal, the electronic device 200 enters a second mode at step S190. Here, an electronic device, such as a digital camera, an electric iron, a digital wrist watch, a portable display device, a hair dryer, or a vacuum cleaner, which are in the first mode (i.e., an idle state) starts to be operated in the second mode. Furthermore, an electric fan in the first mode (i.e., an operating state) enters the second mode in which the operation is stopped. Meanwhile, a toilet seat is operated at an optimal temperature in the second mode because the first mode has the lowest temperature.

In this state, the electronic equipment mode switching apparatus 200 determines whether skin contact remains intact at step S210. Whether skin contact remains intact is determined by determining whether electricity continues to be generated from the user's skin. If the user's skin is taken off from the electronic equipment mode switching apparatus 100, electricity is no longer generated from the user's skin. If, as a result of the determination at step S210, the skin contact remains intact, it is determined whether discharging has been completed through the timer 111 at step S230. If, as a result of the determination at step S230, discharging has been completed through the timer 111, it means that the user is in one of a mode in which the user has stopped using the electronic device 200, a mode in which the electronic device 200 has stopped operating, and a mode in which the electronic device 200 has returned to a safe state. In this case, the electronic equipment mode switching apparatus 100 generates a signal for switching the mode of the electronic device 200 to the electronic equipment mode switching means 210 of the electronic device 200 at step S250.

In response to the signal, the electronic device 200 returns to the first mode at step S270.

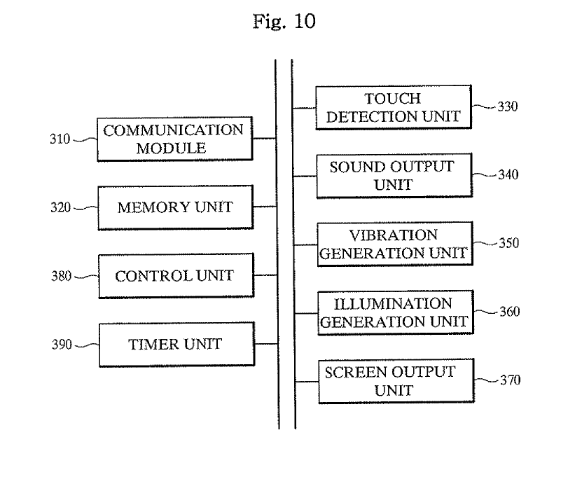

FIG. 10 is a block diagram of a mobile phone capable of switching a call incoming alarming mode on the basis of a skin contact when a call is received according to an embodiment of the present invention. The mobile phone capable of switching a call incoming alarming mode on the basis of a skin contact when a call is received according to the embodiment of the present invention, as shown in FIG. 10, includes a communication module 310, a memory unit 320, a touch detection unit 330, a sound output unit 340, a vibration generation unit 350, an illumination generation unit 360, a screen output unit 370, a control unit 380, and a timer unit 390.

Here, the communication module 310 includes a transceiver unit configured to enable communication between the mobile phone of the present invention and a mobile communication network which provides mobile communication services to mobile phones.

The memory unit 320 stores at least one of a sound output mode, a vibration generation mode, an illumination generation mode, a silence mode, and a screen output mode which has been set for a call received through the communication module 310 over the mobile communication network in the case in which the call incoming alarming mode of the mobile phone is set to the corresponding mode.

The touch detection unit 330 detects the skin of the human body, including a user, when a call is received by the mobile phone over the mobile communication network. The touch detection unit 330 can be formed of an electrostatic touch sensor or a pressure-sensitive touch sensor or can be formed of an electronic equipment mode switching apparatus, such as that shown in FIGS. 1 and 2.

The sound output unit 340 outputs sound if the call incoming alarming mode is the sound output mode when a call is received by the mobile phone over the mobile communication network.

The vibration generation unit 350 generates vibration if the call incoming alarming mode is the vibration generation mode when a call is received by the mobile phone over the mobile communication network.

The illumination generation unit 360 generates illumination if the call incoming alarming mode is the illumination generation mode when a call is received by the mobile phone over the mobile communication network. Such illumination can be formed of LED illumination.

The screen output unit 370 displays a screen if the call incoming alarming mode is the screen output mode when a call is received by the mobile phone over the mobile communication network. In general, the illumination is automatically turned off after a lapse of a set time in order to reduce power consumption in the display unit of a mobile phone. The automatic display of a corresponding display unit can include, for example, displaying a character or a symbol which informs an incoming call.

The control unit 380 determines the call incoming alarming mode, set in the memory unit 310, and a detected result of the touch detection unit 330 when a call is received by the mobile phone over the mobile communication network. Furthermore, the control unit 380 determines whether the skin contact of the human body, including a user, has been detected by the touch detection unit 330 when the call incoming alarming mode is the sound output mode according to a result of the determination. The control unit 380 performs control according to a result of the determination so that the sound output mode is automatically switched to at least one of the vibration generation mode, the illumination generation mode, the silence mode, and the screen output mode.

Meanwhile, in the case in which the touch detection unit 330 is formed of an electronic equipment mode switching apparatus 100, such as that shown in FIGS. 1 and 2, the function of the electronic equipment mode switching means 210 within the electronic device 200 can be performed by the control unit 380.

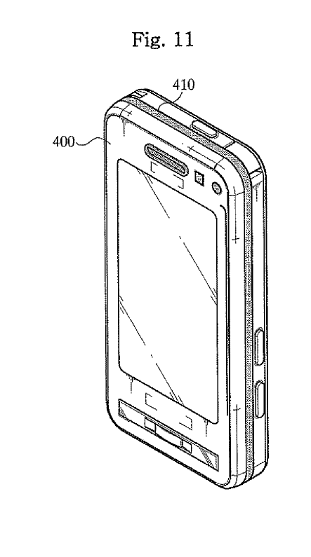

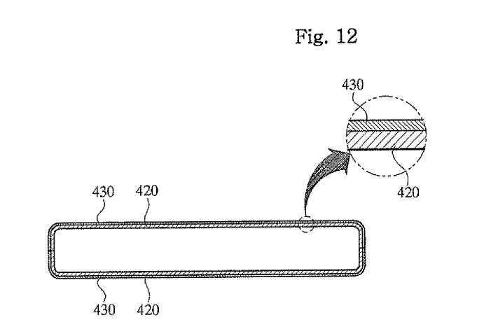

In the mobile phone of the present invention, in order to more easily detect the skin contact of a user on the mobile phone, it is preferred that a material (e.g., aluminum (Al)) for allowing an electrical signal, generated from the skin when the skin is touched, to be easily transferred to the touch detection unit 330 be deposited on a casing constituting the surface of the mobile phone. This is described with reference to FIGS. 11 and 12.

FIG. 11 is a diagram showing a state in which a conductive material is formed in a mobile phone according to a first embodiment of the present invention. In the state in which the conductive material is formed in the mobile phone according to the first embodiment of the present invention, as shown in FIG. 11, a thin metal plate 410 is put around on a portion to which a mobile phone casing is adhered, from the outer circumstantial surface of the mobile phone 400, in the form of a belt.

FIG. 12 is a diagram showing a state in which a conductive material is formed in a mobile phone according to a second embodiment of the present invention. In the state in which the conductive material is formed in the mobile phone according to the second embodiment of the present invention, as shown in FIG. 12, a thin metal film 430 can be deposited on the outer circumferential surface of the mobile phone casing 420 using a physical vapor deposition (PVD) method.

As described above, in FIG. 11 or 12, the thin metal plate 410 is formed or the thin metal film 430 is deposited in the part or the outer circumferential surface to which the casing of the mobile phone is adhered. Accordingly, there is an advantage in that an electrical signal generated from the skin of the human body can be more easily detected by the touch detection unit 330.

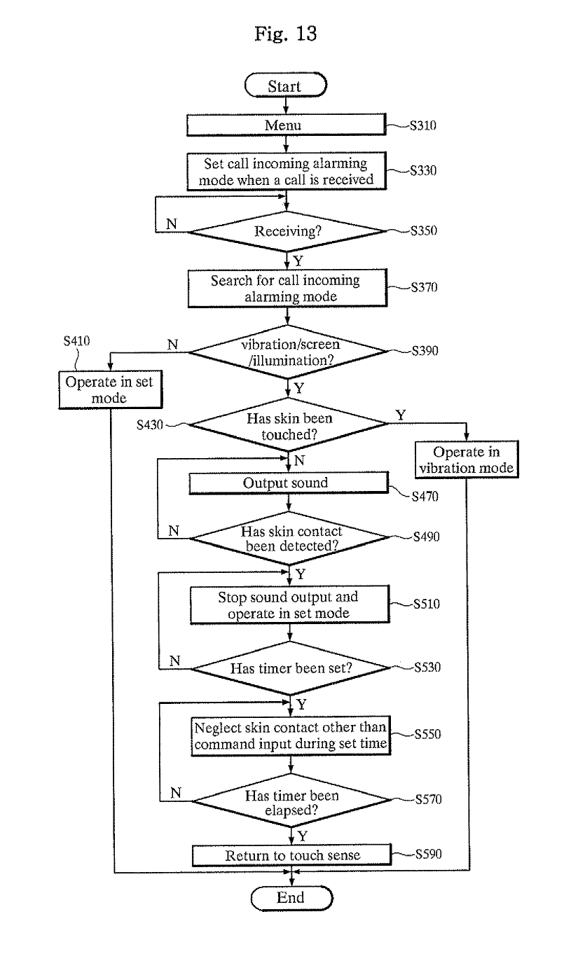

FIG. 13 is a flowchart illustrating a method of automatically switching the call incoming alarming mode of a mobile phone on the basis of a skin contact when a call is received according to an embodiment of the present invention. In the method of automatically switching the call incoming alarming mode of the mobile phone according to the embodiment of the present invention, as shown in FIG. 13, first, a menu item is selected in the mobile phone at step S310.

When a call is received, an alarming mode is set in the menu item at step S330. The set alarming mode when a call is received can include at least one of a sound output mode in which sound is output, a vibration generation mode in which vibration is generated, an illumination generation mode in which illumination is generated, a screen output mode in which a screen is output, and a silence mode. Furthermore, if the sound output is stopped when the skin is touched, one of the vibration generation mode, the screen output mode, the illumination generation mode, and the silence mode can be set to the alarming mode. It is then determined whether an incoming call is received through the communication module 310 of the mobile phone at step S350. If, as a result of the determination at step S350, the incoming call is received, the alarming mode is searched for at step S370.

Next, it is determined which one of the vibration generation mode, the screen output mode, the illumination generation mode, and the silence mode is set as the alarming mode at step S390. If, as a result of the determination at step S390, the alarming mode is set to one of the vibration generation mode, the screen output mode, the illumination generation mode, and the silence mode, the mobile phone is operated in the corresponding mode at step S410.

However, if, as a result of the determination at step S390, the alarming mode is not set to any one of the vibration generation mode, the screen output mode, the illumination generation mode, and the silence mode, it is determined whether a user's skin is touching the touch detection unit 330 at step S430.

If, as a result of the determination at step S430, the user's skin is touching the touch detection unit 330, the mobile phone is operated in the vibration generation mode at step S450.

However, if, as a result of the determination at step S430, the user's skin is not touching the touch detection unit 330, sound is output at step S470.

It is then determined whether skin contact is detected by the touch detection unit 330 at step S490.

If, as a result of the determination at step S490, skin contact is not detected by the touch detection unit 330, the sound output remains intact at step S470.

However, if, as a result of the determination at step S490, skin contact is detected by the touch detection unit 330, the sound output is stopped and the mobile phone is operated in a set mode at step S510. The set mode can include one of the vibration generation mode, the screen output mode, the illumination generation mode, and the silence mode.

It is then determined whether time has been set in the timer unit 390 at step S530. In other words, if the time is set in the timer unit 390, a change in the sound output mode according to unnecessary skin contact (e.g., slight graze) can be prevented.

If, as a result of the determination at step S530, the time has been set, skin contacts except the input of a command is neglected during the set time at step S550. This function has been made by taking the function of a recent touch mobile phone into consideration.

It is then determined whether the set time has elapsed at step S570.

If, as a result of the determination at step S570, the set time has elapsed, skin contact is enabled at step S590.

As described above, the present invention has the following advantages.

First, an electronic device can be operated or stopped or can output different power levels according to a user's skin contact with the electronic device. Accordingly, electronic devices can be used more conveniently and safely.

Second, an electronic device can be operated or stopped according to a user's skin contact with the electronic device. Accordingly, power consumption can be minimized.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

1. An electronic equipment mode switching apparatus based on a skin contact, comprising:
skin contact detection means 110 for detecting electricity generated when a user's skin is touched;
logic circuit means 120 for generating a mode switching signal to switch a power supply mode of an electronic device 200 when skin contact is detected by the skin contact detection means 110; and
mode switching means 130 for switching the power supply mode of the electronic device 200 in response to the mode switching signal generated by the logic circuit means 120.

2. The electronic equipment mode switching apparatus as claimed in claim 1, wherein the skin contact detection means 110 comprises:
a first switching unit Q1 switched on or off according to the electricity generated when the user's skin is touched, and
a first timer 111 charged or discharged in response to the on or off switching of the first switching unit Q1.

3. The electronic equipment mode switching apparatus as claimed in claim 1, wherein the logic circuit means 120 comprises a Schmidt trigger circuit and a flip-flop circuit sequentially configured.

4. The electronic equipment mode switching apparatus as claimed in claim 1, wherein the mode switching means 130 comprises a second switching unit Q2 switched on or off in response to the mode switching signal generation of the logic circuit means 120.

5. The electronic equipment mode switching apparatus as claimed in claim 1, wherein the electronic device 200 is operated according to one of a power-on mode, a power-off mode, a first electric power mode, and a second electric power mode relatively higher than the first electric power mode according to the power supply mode.

6. The electronic equipment mode switching apparatus as claimed in claim 1, wherein:
the power supply mode of the electronic device 200 is switched by the electronic equipment mode switching apparatus based on a skin contact, and
the electronic device 200 comprises one of a digital camera, an electric iron, a toilet seat, a digital wrist watch, a portable display device, a hair dryer, a vacuum cleaner, and an electric fan.

7. The electronic equipment mode switching apparatus as claimed in claim 6, wherein:
the electronic equipment mode switching apparatus is configured in a place touched by a left hand of a user who uses the digital camera,
the electronic equipment mode switching apparatus is configured in a handle part of the electric iron, the hair dryer, or the vacuum cleaner,
the electronic equipment mode switching apparatus is configured on a top surface of the toilet seat,
the electronic equipment mode switching apparatus is configured in a part touched by a back of a hand of a user, from the digital wrist watch,
the electronic equipment mode switching apparatus is configured in a frame formed in an outer circumference of the portable display device, and
the electronic equipment mode switching apparatus is configured in a main body of the electric fan other than a switch part of the electric fan and in a protection net protecting wings of the electric fan.

8. The electronic equipment mode switching apparatus as claimed in claim 7, wherein a material having excellent conductivity is adhered to the place touched by the left hand of the user who uses the digital camera, the handle part of the electric iron, the hair dryer, or the vacuum cleaner, the top surface of the toilet seat, the part touched by the back of the hand of the user, from the digital wrist watch, the outer circumferential frame of the portable display device, and the main body of the electric fan and the protection net protecting wings of the electric fan.

9. A mode switching method of the electronic equipment mode switching apparatus according to claim 1, the method comprises the steps of:
when a skin is touched in a first mode in which an electronic device driven by electricity is operating or idle, generating a signal for switching a mode of the electronic device to electronic equipment mode switching means for switching a power supply mode of the electronic device;
the mode of the electronic device entering a second mode;
making a determination of whether the skin remains touched and, if, as a result of the determination, the skin does not remain touched, generating a signal for switching a mode of the electronic device to the electronic equipment mode switching means of the electronic device; and
the electronic device returning to the first mode.

10. The mode switching method as claimed in claim 9, wherein:
the first mode is a stop state when the electronic device is one of a digital camera, an electric iron, a digital wrist watch, a portable display device, a hair dryer, and a vacuum cleaner, the first mode is an operating state when the electronic device is an electric fan, and the first mode is an operating state at a lowest temperature when the electronic device is a toilet seat, and
the second mode is an operating state when the electronic device is one of a digital camera, an electric iron, a digital wrist watch, a portable display device, a hair dryer, and a vacuum cleaner, the second mode is a stop state when the electronic device is an electric fan, and the second mode is an operating state at an optimal temperature when the electronic device is a toilet seat.

11. A mobile phone capable of switching a call incoming alarming mode based on a skin contact when a call is received, the mobile phone comprising:
a communication module 310 for providing communication between the mobile phone and a mobile communication network;
a memory unit 320 for storing at least one of a sound output mode, a vibration generation mode, an illumination generation mode, a silence mode, and a screen output mode, which is set as the call incoming alarming mode of the mobile phone for the call received through the communication module 310 over the mobile communication network;
a touch detection unit 330 for detecting a skin contact when the call is received over the mobile communication network; and
a control unit 380 for performing control so that the sound output mode is switched to at least one of the vibration generation mode, the illumination generation mode, the silence mode, and the screen output mode when the skin contact is detected by the touch detection unit 330 in a state in which the call incoming alarming mode is the sound output mode, based on the call incoming alarming mode set in the memory unit 320 when the call is received and a result of the detection of the touch detection unit 330.

12. The mobile phone as claimed in claim 11, further comprising at least one of:
a sound output unit 340 for outputting sound when the call is received,
a vibration generation unit 350 for generating vibration when the call is received,
an illumination generation unit 360 for generating illumination when the call is received, and
a screen output unit 370 for outputting a screen when the call is received.

13. The mobile phone as claimed in claim 11, wherein the touch detection unit 330 comprises one of:
an electrostatic touch sensor,
a pressure-sensitive touch sensor, and
an electronic equipment mode switching apparatus 100, comprising skin contact detection means 110 for detecting electricity generated when a user's skin is touched, logic circuit means 120 for generating a mode switching signal to switch a power supply mode of an electronic device 200 when skin contact is detected by the skin contact detection means 110, and mode switching means 130 for switching the power supply mode of the electronic device 200 in response to the mode switching signal generated by the logic circuit means 120.

14. The mobile phone as claimed in claim 11, wherein metal for transferring an electrical signal, generated from the skin when the skin is touched, to the touch detection unit 330 is deposited on a casing constituting a surface of the mobile phone.

15. A method of switching a call incoming alarming mode of a mobile phone according to claim 11, the method comprising the steps of:
when a call is received by the mobile phone, setting the call incoming alarming mode;
when a call is received by the mobile phone, searching for the call incoming alarming mode and, if, as a result of the search, the call incoming alarming mode is a sound output mode, making a determination of whether the mobile phone is touching a user's skin;
if, as a result of the determination, the mobile phone is not touching the user's skin, outputting sound;
making a determination of whether the user's skin is touching the mobile phone during the sound output; and
if, as a result of the determination, the user's skin is touching the mobile phone during the sound output, stopping the sound output and switching the call incoming alarming mode to a mode other than the sound output.

16. The method as claimed in claim 15, wherein the step of making a determination of whether the mobile phone is touching a user's skin includes making a determination of whether the mobile phone is touching the user's skin for a predetermined time or more.

17. The method as claimed in claim 15, wherein the step of switching the call incoming alarming mode to a mode other than the sound output includes switching the call incoming alarming mode to at least one of a vibration generation mode in which vibration is generated, an illumination generation mode in which illumination is generated, a screen output mode in which a screen is output, and a silence mode.

18. The method as claimed in claim 15, wherein a timer is driven for a time set after the call incoming alarming mode is automatically switched to a mode other than the sound output mode in the mode other than the sound output mode when the skin contact is detected, and a skin contact except a command input is neglected.
